(19) United States
(12) Patent Application Publication
(10) Pub. No.: US 2012/0211886 A1
(43) Pub. Date: Aug. 23, 2012

(54) Method for Fabricating a Small Footprint Chip-Scale Package and a Device Made from the Method

(75) Inventors: Peter Lieu, Irvine, CA (US); James Yamaguchi, Laguna Niguel, CA (US); Randy Bindrup, Trabucco Canyon, CA (US); W. Eric Boyd, Long Beach, CA (US)

(73) Assignee: ISC8 Inc., Costa Mesa, CA (US)

(21) Appl. No.: 13/399,051

(22) Filed: Feb. 17, 2012

Related U.S. Application Data
(63) Continuation-in-part of application No. 13/230,369, filed on Sep. 12, 2011.
Application No. 13/230,369 is a continuation-in-part of application No. 13/271,797, filed on Oct. 12, 2011.
(60) Provisional application No. 61/444,860, filed on Feb. 21, 2011.

(51) Int. Cl. H01L 23/498; H01L 21/50

(52) U.S. Cl. 257/737; 438/127; 257/E21.499; 257/E23.068

(57) ABSTRACT

A method for fabricating an integrated circuit chip-scale package and a device made from the method. One or more IC chips are mounted on a carrier and a stud bump defined on an IC pad. The stud-bumped IC is encapsulated to define a potted assembly layer which is thinned to expose the stud bump. Conductive first traces are defined and coupled to the stud bump to reroute the IC pads. A dielectric layer is provided and vias defined there through to expose the first traces. Electrically conductive second traces are disposed on the dielectric layer surface that are coupled to the first traces to reroute the IC pads to define a chip scale package.

### CROSS-REFERENCE TO RELATED APPLICATIONS

This application claims the benefit of U.S. Provisional Patent Application No. 61/444,860, filed on Feb. 21, 2011 entitled “Small Footprint Chip Scale Package from a Single Die” pursuant to 35 USC 119, the entire contents of which is incorporated herein by reference.

This application is a continuation-in-part application of U.S. patent application Ser. Nos. 13/230,369, now pending, filed on Sep. 12, 2011 and is a continuation-in-part application of U.S. patent application Ser. No. 13/271,797, now pending, filed on Oct. 12, 2011 pursuant to 35 USC 119, the entire contents of each of which are incorporated herein by reference.

### STATEMENT REGARDING FEDERALLY SPONSORED RESEARCH AND DEVELOPMENT

N/A

### BACKGROUND OF THE INVENTION

1. Field of the Invention

The invention relates generally to the field of stacked integrated circuits. More specifically, the invention relates to using conductive stud bumps with bare integrated circuit die and potting for fabricating a chip scale package comprising an integrated circuit chip.

2. Description of the Related Art

The ability to fabricate very thin, chip scale packages (“CSP”s) is desirable and allows high density, high speed electronic systems to be assembled for use in military, space, security and other applications.

Modified integrated circuit chips, in the form of layers and modules are disclosed in, for instance, U.S. Pat. No. 6,072,234, Stack of Equal Layer Neo-Chips Containing Encapsulated IC Chips of Different Sizes; U.S. Pat. No. 6,797,537, Method of Making Stackable Layers Containing Encapsulated Integrated Circuit Chips With One or More Overlying Interconnect Layers; U.S. Pat. No. 6,784,547, Stackable Layers Containing Encapsulated Integrated Circuit Chips With One or More Overlying Interconnect Layers; U.S. Pat. No. 6,117,704, Stackable Layer Containing Encapsulated Chips, U.S. Pat. No. 6,072,234; Stack of Equal Layer Neo-Chips Containing Encapsulated IC Chips of Different Sizes, U.S. Pat. No. 5,953,588; Stackable Layers Containing Encapsulated IC Chips, and U.S. Pat. No. 7,768,113; Stackable Tier Structure Comprising Prefabricated High Density Feed-through.

The present invention provides a chip scale package comprising a rerouted integrated circuit chip (which integrated circuit chip is also herein referred to as an “IC” or “die”). The use of potted and thinned chip scale packages having rerouted. die therein permits an IC package to be provided having an X-Y footprint approximately that of the die itself.

A prior art process for making a “neo-chip” or “neo-layer” from an IC chip involves the “potting” of individual IC chips in a encapsulant or compound which supports and insulates the chip and which can be cut or diced to provide a chip scale package. The individual chips, in die form, may be incorporated into neo-wafer form for batch processing. Thereafter, the ICs are cut out of the neo-wafer in the form of a chip scale package.

The prior art neo-chip processes may include the processing of chips purchased as individual die. Beneficially, chips purchased as individual die are generally “known good” die which have been “burned in” and are therefore pre-tested prior to stacking.

Prior to processing, one or more known good die are used to create a “neo” wafer by locating those known good die in a potting fixture. Potting material is flowed into the fixture, which is enclosed and then the potting material is cured. The resulting “neo-wafer” is removed from the fixture and then subjected to process steps including spinning on a layer of dielectric material, forming vias through the dielectric material to reach the terminals on the die in the wafer, and then forming electrical conductors in the form of metal traces that lead from the die terminals on the surface of the dielectric layer or layers. Thereafter the neo-wafer is diced into one or more layers which, in one embodiment, are suitable for stacking, each layer containing at least one known good die.

Each layer of a completed stack has electrical leads in the form of conductive metal traces used to connect the IC circuitry of the embedded chip (or chips) to one or more access planes, where the traces are available for connection to exterior circuitry. Such neo-processes are modifiable and adaptable to provide a chip scale package from the die.

Major cost-saving benefits can be obtained by the sole use of “known good” die, and the use/of a neo-wafer in processing one or more of such die.

Neo-chips offer significant improvements over silicon bare die in certain applications, but have also proved troublesome under certain market circumstances. In particular, it is often difficult to buy bare die because many manufacturers will only sell packaged die.

For instance, when trying to buy bare DRAM die from a particular manufacturer, it was discovered that the manufacturer would not sell bare DRAM die, but would sell the DRAM die already pre-tested and installed in prepackaged integrated circuit packages.

Because of the demand for die and the high capital investment necessary to be a mass manufacturer of them, it is difficult to induce a mass fabricator of die to supply only die as opposed to the usual finished product which is a packaged or encapsulated integrated circuit chip. Such mass fabricators are typically fully occupied with the manufacture of finished and packaged integrated circuits. Individual IC chips are not typically offered for sale either in wafer or in die form.

Even in those cases where a mass fabricator can be induced to manufacture and sell a bare functional die, the die may be delivered in wafers or diced without testing. In other words, a die is normally tested after it is connected to its lead frame and packaged on a lead frame or in an encapsulant to ascertain whether it is operable as intended. Mass testing of bare die is not a procedure that many mass fabricators are equipped or even inclined to do. Therefore, a purchaser of bare die must test each die individually in order to determine its operability or the yield. Bare die testing is too limited to ensure acceptable yields, while comprehensive testing and burn-in renders bare die production cost-ineffective. These problems are sometimes referred to as the “known good die” or “KGD” problem.

Because prepackaged die are burned in and therefore contain known good die, it is desirable to depackage known good die within a prepackaged IC package for use in certain applications such as for use in the above neo-processes.

Unfortunately, for both die obtained as bare die and depackaged die, during the processing steps of neowafer fabrication, certain elements of the bare die, particularly the aluminum contact pads, are prone to corrosion caused by chemicals used during lithography or elsewhere in the process; particularly corrosion on the side aluminum walls of the IC contact pads when nickel and palladium are present on the surface of the aluminum contact pads.

Additionally, some circuit elements on the bare die that are used in the neolayer process are sensitive to the radiation used in certain process steps and can he damaged by exposure thereto.

What is needed is a neo-chip fabrication method that protects the aluminum IC pads from corrosion and any active IC circuit elements from radiation during processing and that provides a neo-chip for use as a chip scale package.

### BRIEF SUMMARY OF THE INVENTION

A method for fabricating an integrated circuit chip scale package and a device made from the method are disclosed.

One or more individual integrated circuit die are mounted on a sacrificial carrier and a metal stud bump defined on the contact or bond pad of the integrated circuit die.

The stud-bumped die is encapsulated in a potting material to define a potted assembly layer.

A predetermined portion of the cured potting material is removed from the potted assembly whereby a portion of the stud bump is exposed. One or more electrically conductive first traces are defined on the potted assembly layer surface and are electrically coupled to the stud bump to reroute the integrated circuit bond pad to predetermined locations on the assembly. A subsequent dielectric layer may be provided over the surface of the potted assembly layer, one or more vias defined there through to expose a portion of the electrically conductive first traces and one or more electrically conductive second traces provided on the dielectric layer that are electrically coupled to the exposed portions of the first traces for the rerouting of the IC I/O pads to a predetermined location.

In a first aspect of the invention, a method for fabricating an integrated circuit chip scale package is provided comprising the steps of bonding an integrated circuit die to a sacrificial carrier, defining a stud bump on the contact pad of an integrated circuit die, encapsulating the die in a potting material to define a potted assembly layer having an active surface and an inactive surface, removing a portion of the potting material from the active surface to a predetermined first depth whereby a predetermined portion of the stud bump is exposed on the active surface, and defining one or more electrically conductive first traces on the active surface that are electrically coupled to the stud bump.

In a second aspect of the invention method may comprise the further step of providing a post-potting dielectric layer.

In a third aspect of the invention, the method may comprise the further step of defining a via in the post-potting dielectric layer to expose a portion of the electrically conductive first trace and defining an electrically conductive second trace on the surface of the dielectric layer that is electrically coupled to the first trace through the via.

In a fourth aspect of the invention, the method may comprise the step of back-thinning the inactive surface to a predetermined second depth to define a final layer thickness.

In a fifth aspect of the invention, the die may be a die that has been processed by the steps of providing an integrated circuit chip having improved planar uniformity from a prepackaged integrated circuit package comprising the steps of providing a prepackaged integrated circuit package comprising an integrated circuit die, removing a predetermined portion of the package in a first operation to define a partially-depackaged integrated circuit die, affixing the partially-depackaged integrated circuit die and a spacer element having a predetermined thickness and a predetermined set of surface dimensions to a substrate whereby a least a portion of the spacer element is disposed between the partially-depackaged integrated circuit die and the substrate to define a convex, partially-depackaged integrated circuit die surface, and, removing a predetermine portion of the convex, partially-depackaged integrated circuit die surface in a second operation.

These and various additional aspects, embodiments and advantages of the present invention will become immediately apparent to those of ordinary skill in the art upon review of the Detailed Description and any claims to follow.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 shows a plurality of integrated circuit die bonded to a sacrificial substrate with a stud bump applied to the contact pads of the die. If the die is provided with an existing insulating layer over the existing contact pads of the die, it is necessary to define a via in the insulating layer at the desired locations to expose the conductive IC contact pads under the insulating layer.

FIG. 2 depicts the die encapsulated in a potting material to define a potted assembly layer.

FIG. 3 illustrates the potted die after the active surface has been lapped to a predetermined first depth to expose a portion of a stud bump.

FIG. 4 depicts the exposed stud bumps electrically coupled to a set of electrically conductive first traces that have been defined over the potting material on the active surface of the potted assembly layer for the rerouting of the IC pads predetermined locations.

FIG. 5 illustrates the rerouted die of FIG. 4 having a first dielectric layer defined over its active surface with vias defined therein to expose a portion of the first traces.

FIG. 6 shows the assembly of FIG. 5 having a second set of electrically conductive second traces defined over the surface of first dielectric layer and electrically coupled to the first traces through the vias.

FIG. 7 shows the assembly of FIG. 6 having a second dielectric layer defined over the first dielectric layer surface with vias defined therein to expose a portion of the second traces.

FIG. 8 depicts the assembly of FIG. 7 with the sacrificial substrate removed

FIG. 9 illustrates the assembly of FIG. 8 after back-thinning to remove a predetermined portion of the inactive surface of the assembly.

FIG. 10 shows a preferred embodiment of the invention after it has been diced to a predetermined size with solder balls electrically coupled to portions of exposed second traces for connection to a printed circuit board.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like numerals define like elements among the several views, a method for fabricating an integrated circuit chip scale package using conductive metal stud bumps, such as gold stud bumps applied from a wire bonding machine, is disclosed.

The invention addresses deficiencies in the prior art known to occur during the potting and lamination of bare integrated circuit die. The method of the invention addresses the prior art problem associated with integrated circuits that are susceptible to damage from UV radiation during neoprocessing by protecting active IC surfaces with a potting compound. The method of the invention also protects aluminum pads on bare integrated circuit die from corrosion caused by chemicals used during lithography or elsewhere in the neolayer process by minimizing corrosion on the side walls of aluminum IC contact pads when nickel and palladium are present on the surface thereof.

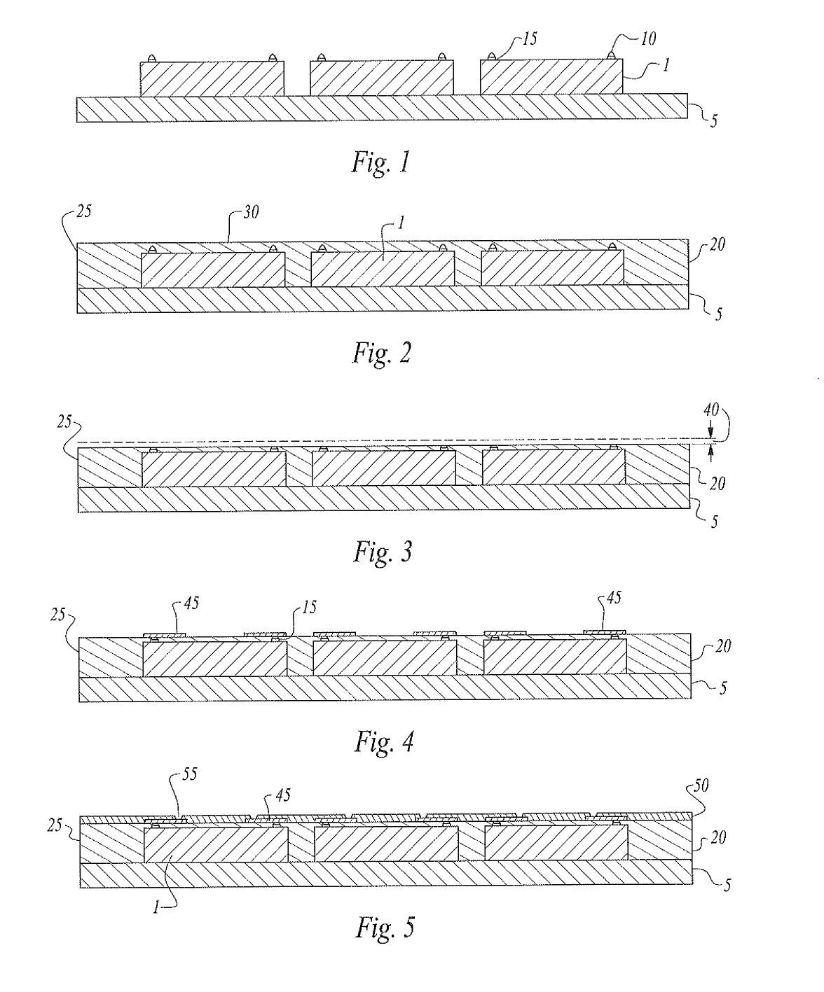

As illustrated in FIG. 1, one or more integrated circuit die 1 are bonded with their active die surface with I/O bond pads face up to a sacrificial substrate 5 such as a silicon, FR-4 or aluminum substrate material. An electrically conductive stud bump 10, preferably comprised of a gold material, is defined on one or more bond pads 15 of a bare integrated circuit or “IC” die 1 such as by means of wire-bonder.

Suitable wire bond equipment to practice the process of the invention is available from West Bond, Inc. Stud bump 1 is preferably about 65 μ in height.

In one embodiment of the invention, integrated circuit die 1 may be a depackaged, known good die or a depackaged, improved planar uniformity integrated circuit die, or both, that has been prepared by the process disclosed in U.S. patent application Ser. No. 13/230,369, entitled “Method for Depackaging Prepackaged Integrated Circuit Die and a Product Made from the Method”, now pending.

In one aspect of the planarized depackaged known good die invention disclosed in the above referenced U.S. patent application Ser. No. 13/230,369,a process for providing an integrated circuit die having improved planar uniformity from a prepackaged integrated circuit package is disclosed comprising the steps of providing a prepackaged integrated circuit package comprising an integrated circuit die, removing a predetermined portion of the package in a first operation to define a partially-depackaged integrated circuit die, affixing the partially-depackaged integrated circuit die and a spacer element having a predetermined thickness and a predetermined set of surface dimensions to a substrate whereby a least a portion of the spacer element is disposed between the partially-depackaged integrated circuit die and the substrate to define a convex, partially-depackaged integrated circuit die surface and removing a predetermined portion of the material to a predetermined depth from the convex, partially-depackaged integrated circuit die surface in a second operation.

The resultant depackaged die of the above process has improved planar uniformity and is well-suited for use in the instant method and device of the invention.

With respect to FIG. 2, die I., which illustrates a batch fabrication using multiple individual die 1 bonded to substrate 5, is encapsulated in an insulating potting material 20, i.e., is “potted” using a suitable potting encapsulant, which material may be a silica-filled epoxy. As is illustrated, once sufficient potting material. 20 is added to the potting mold or fixture, die 1 and stud bumps 10 thereon are completely covered, i.e., encapsulated in the material, beyond the upper surfaces of the stud bumps 10.

The potting compound 20 is then “cured” per the manufacturer's specifications and a cured, potted assembly layer 25 is defined having an active surface 30 and an inactive surface 35.

As depicted in FIG. 3, a portion of potting material 20 on active surface 30 is removed. to a predetermined first depth 40 using a grinding, lapping or chemical-mechanical polishing (CMP) process until a predetermined portion of stud bump 10 is exposed on the active surface for use as an electrical rerouting contact for subsequent metal traces and preferably remains surrounded by a portion of potting material 20.

As best seen in FIG. 4, a set of one or more electrically conductive first traces 45 are defined over the potting material 20 defining active surface 30 to provide desired electrical reroutes and/or interconnections. First traces 45 are preferably delineated by photolithography and metal deposition and plating processes, or by equivalent means.

As illustrated in FIG. 5, a first dielectric layer 50 is applied using suitable compounds including, but not limited to a polyimide-, BCB-, or epoxy-based dielectric compounds.

One or more vias 55 are then defined or “opened” in first dielectric layer 50 using conventional photolithographic and etching processes to expose a portion of first traces 45 to permit the defining of additional layers of metal traces that are electrically coupled with selected exposed first trace portions that are accessible within vias 55.

Depending on the end use of the chip scale package of the invention, additional vias and layers of dielectric material and metal trace layers may be built up the surface of the first dielectric layer 50 by following the procedure described in the previous step to create a high density, high I/O multilayer conductive structure on the surface of die 1.

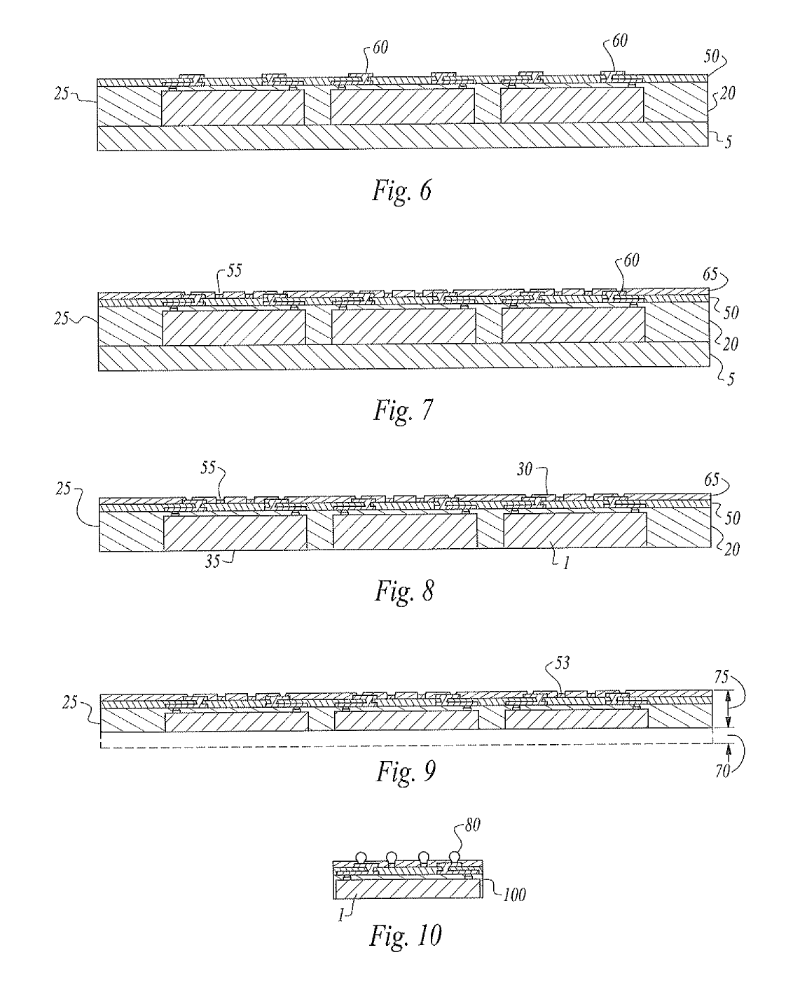

FIG. 6 depicts the assembly of FIG. 5 where a set of conductive metal second traces 60 are defined on the surface of first dielectric layer 50 and electrically coupled to the exposed portion of the first traces 45 by means of vias 55 through first dielectric layer 50.

FIG. 7 illustrates the assembly of FIG. 6 having a second dielectric layer 65 defined on active surface 30 and having one or more vias 55 defined there-through to expose a portion of conductive second traces 60.

As seen in FIG. 8, sacrificial substrate 5 is removed from the inactive surface 35 of the assembly to expose the inactive surface of the die 1.

Turning to FIG. 9, after the second dielectric layer 65 is cured, the inactive surface 35 of potted assembly layer 25 is back-thinned to a predetermined second depth 70 to define a predetermined final layer thickness 75.

As shown in FIG. 10, the potted assembly layer 25 has one or more solder balls 80 applied on exposed portions of second traces 60 and the assembly is then diced to its final preferred X-Y dimensions to provide a chip scale package 100 comprising a stud bumped bare integrated circuit die.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must. be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

We claim:

1. A method for fabricating an integrated circuit chip scale package comprising the steps of:
bonding an integrated circuit die to a sacrificial carrier,
defining a stud bump on a contact pad of the integrated circuit die,
encapsulating the die in a potting material to define a potted assembly layer having an active surface and an inactive surface,
removing a portion of the potting material from the active surface to a predetermined first depth whereby a portion of the stud bump is exposed on the active surface,
defining one or more electrically conductive first traces on the active surface that are electrically coupled to the stud bump,
defining a first dielectric layer on the active surface,
defining a via in the first dielectric layer to expose a portion of the electrically conductive first trace,
defining an electrically conductive second trace on the surface of the first dielectric layer that. is electrically coupled to the first trace through the via, and,
back-thinning the inactive surface to a predetermined second depth to define a final layer thickness.

2. The method of claim I wherein the die is a prepackaged integrated circuit package has been processed by the steps of:
removing a predetermined portion of the package in a first operation to define a partially-depackaged integrated circuit die,
affixing the partially-depackaged integrated circuit die and a spacer element having a predetermined thickness and a predetermined set of surface dimensions to a substrate whereby at least a portion of the spacer element is disposed between the partially-depackaged integrated circuit die and the substrate to define a convex, partially-depackaged integrated circuit die surface, and,
removing a predetermined portion of the convex, partially-depackaged integrated circuit die surface in a second operation.

3. A chip scale package fabricated from a process comprising the steps of:
bonding an integrated circuit die to a sacrificial carrier,
defining a stud bump on a contact pad of the integrated circuit die,
encapsulating the die in a potting material to define a potted assembly layer having an active surface and an inactive surface,
removing a portion of the potting material from the active surface to a predetermined first depth whereby a portion of the stud bump is exposed on the active surface,
defining one or more electrically conductive first traces on the active surface that are electrically coupled to the stud hump,
defining a first dielectric layer on the active surface,
defining a via in the first dielectric layer to expose a portion of the electrically conductive first trace,
defining an electrically conductive second trace on the surface of the first dielectric layer that is electrically coupled to the first trace through the via, and,
back-thinning the inactive surface to a predetermined second depth to define a final layer thickness.

4. The chip scale package of claim 3 wherein the die is a prepackaged integrated circuit package processed by the steps of:
removing a predetermined portion of the package in a first operation to define a partially-depackaged integrated circuit die,
affixing the partially-depackaged integrated circuit die and a spacer element having a predetermined thickness and a predetermined set of surface dimensions to a substrate whereby at least a portion of the spacer element is disposed between the partially-depackaged integrated circuit die and the substrate to define a convex, partially-depackaged integrated circuit die surface, and,
removing a predetermined portion of the convex, partially-depackaged integrated circuit die surface in a second operation.
